(19) United States
(12) Patent Application Publication
(10) Pub. No.: US 2024/0402027 A1
(43) Pub. Date: Dec. 5, 2024

(54) ENVIRONMENT DATA MONITORING METHOD, ENVIRONMENT DATA MONITORING SYSTEM, AND ENVIRONMENT DATA MONITORING APPARATUS

(71) Applicant: WISTRON NEWEB CORPORATION, HSINCHU (TW)

(72) Inventors: CHIA-HSIN WU, HSINCHU (TW); TING-HUEI CHEN, HSINCHU (TW); FU-MING KANG, HSINCHU (TW)

(21) Appl. No.: 18/659,118

(22) Filed: May 9, 2024

(30) Foreign Application Priority Data
May 30, 2023 (TW) 112119996

(51) Int. Cl. G01L 13/06; G01P 3/44

(52) U.S. Cl. CPC G01L 13/06; G01P 3/44

(57) ABSTRACT

An environment data monitoring method, an environment data monitoring system, and an environment data monitoring apparatus are provided. The environment data monitoring method includes: obtaining, by a magnetic sensor, a fan rotational speed; obtaining, by a first pressure sensor, a first pressure; obtaining, by a second pressure sensor, a second pressure; calculating, by a controller, a first pressure difference between the first pressure and the second pressure; determining, by the controller, whether or not the fan rotational speed and the first pressure difference reach an alarm standard; and sending, by the controller, an alarm signal when the fan rotational speed and the first pressure difference reach the alarm standard.

### CROSS-REFERENCE TO RELATED PATENT APPLICATION

This application claims the benefit of priority to Taiwan Patent Application No. 112119996, filed on May 30, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a monitoring method and a monitoring system, and more particularly to an environment data monitoring method, an environment data monitoring system, and an environment data monitoring apparatus.

### BACKGROUND OF THE DISCLOSURE

Numerous suspended particles are present in the air. Since the current wafer size has reached a nanometer level, each wafer manufacturing process must be carried out in a micro-clean room. A pressure in the micro-clean room must be greater than a pressure difference outside the micro-clean room, so as to prevent a wafer from contamination of the suspended particles.

In order to keep the pressure in the micro-clean room to be greater than a pressure outside of the micro-clean room, the pressure in the micro-clean room and a rotational speed of a fan in the micro-clean room must be continuously monitored. Conventionally, wired sensors are installed in the micro-clean room, and the wired sensors are electrically connected to an analog digital gateway outside the micro-clean room. When the analog digital gateway receives fan rotational speed data and pressure data from the wired sensors, the analog digital gateway transmits the fan rotational speed data and the pressure data to a monitoring device, and the monitoring device determines whether or not a current environment of the micro-clean room is suitable for the wafer manufacturing process according to the fan rotational speed data and the pressure data.

### SUMMARY OF THE DISCLOSURE

In response to the above-referenced technical inadequacies, the present disclosure provides an environment data monitoring method, an environment data monitoring system, and an environment data monitoring apparatus.

In order to solve the above-mentioned problems, one of the technical aspects adopted by the present disclosure is to provide an environment data monitoring method. The environment data monitoring method includes: obtaining, by a magnetic sensor, a fan rotational speed; obtaining, by a first pressure sensor, a first pressure; obtaining, by a second pressure sensor, a second pressure; calculating, by a controller, a first pressure difference between the first pressure and the second pressure; determining, by the controller, whether or not the fan rotational speed and the first pressure difference reach an alarm standard; and sending, by the controller, an alarm signal when the fan rotational speed and the first pressure difference reach the alarm standard.

In order to solve the above-mentioned problems, another one of the technical aspects adopted by the present disclosure is to provide an environment data monitoring system. The environment data monitoring system includes a magnetic sensor for obtaining a fan rotational speed, a first pressure sensor for obtaining a first pressure, a second pressure sensor for obtaining a second pressure, a main antenna communicatively connected with the magnetic sensor, the first pressure sensor and the second pressure sensor, a radio frequency reader electrically connected to the main antenna, and a controller electrically connected to the radio frequency reader. The controller calculates a first pressure difference between the first pressure and the second pressure and determines whether or not the fan rotational speed and the first pressure difference reach an alarm standard. When the fan rotational speed and the first pressure difference reach the alarm standard, the controller sends an alarm signal.

In order to solve the above-mentioned problems, yet another one of the technical aspects adopted by the present disclosure is to provide an environment data monitoring apparatus. The environment data monitoring apparatus includes a machine device having a chamber and a fan, and an environment data monitoring system. The environment data monitoring system includes a magnetic sensor for obtaining a fan rotational speed, a first pressure sensor for obtaining a first pressure, a second pressure sensor for obtaining a second pressure, a main antenna communicatively connected with the magnetic sensor, the first pressure sensor and the second pressure sensor, a radio frequency reader electrically connected to the main antenna, and a controller electrically connected to the radio frequency reader. The controller calculates a first pressure difference between the first pressure and the second pressure and determines whether or not the fan rotational speed and the first pressure difference reach an alarm standard. When the fan rotational speed and the first pressure difference reach the alarm standard, the controller sends an alarm signal.

Therefore, in the environment data monitoring method, the environment data monitoring system, and the environment data monitoring apparatus provided by the present disclosure, as long as the fan rotational speed, a pressure difference between a pressure inside the chamber and a pressure outside of the chamber, or the pressure inside the chamber is detected to be abnormal, the alarm signal is immediately sent to a monitoring device, so as to eliminate abnormal situations as soon as possible.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of an environment data monitoring method according to a first embodiment of the present disclosure;

FIG. 2 is a flowchart of an environment data monitoring method according to a second embodiment of the present disclosure;

FIG. 3 is a flowchart of an environment data monitoring method according to a third embodiment of the present disclosure;

FIG. 4 is a flowchart of an environment data monitoring method according to a fourth embodiment of the present disclosure;

FIGS. 5A and 5B are flowcharts of an environment data monitoring method according to a fifth embodiment of the present disclosure;

FIG. 6 is a flowchart of an environment data monitoring method according to a sixth embodiment of the present disclosure;

FIG. 7 is a functional block diagram of an environment data monitoring system according to the first embodiment of the present disclosure;

FIG. 8 is a functional block diagram of an environment data monitoring system according to the fifth embodiment of the present disclosure; and

FIG. 9 is a schematic diagram of an environment data monitoring apparatus according to the first embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles may be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. In addition, the term “connect” in the context of the present disclosure means that there is a physical connection between two elements, and the two elements are directly or indirectly connected.

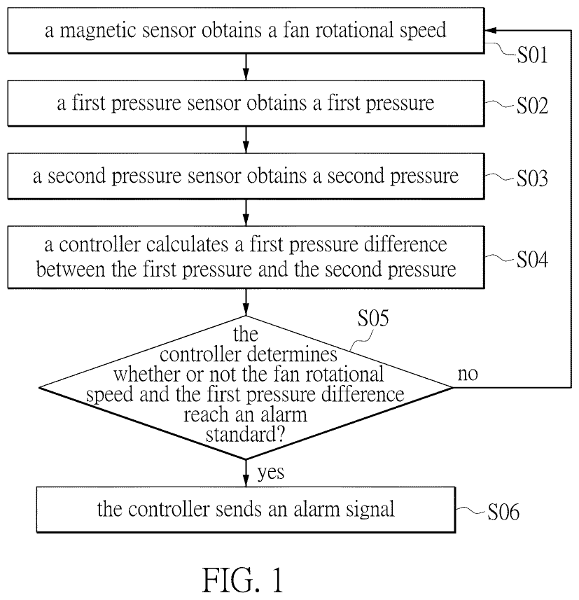

FIG. 1 is a flowchart of an environment data monitoring method according to a first embodiment of the present disclosure. Referring to FIG. 1, in step S01, a magnetic sensor obtains a fan rotational speed. In step S02, a first pressure sensor obtains a first pressure. In step S03, a second pressure sensor obtains a second pressure. In step S04, a controller calculates a first pressure difference between the first pressure and the second pressure. In step S05, the controller determines whether or not the fan rotational speed and the first pressure difference reach an alarm standard. When the fan rotational speed and the first pressure difference reach the alarm standard, step S05 is followed by step S06. In step S06, the controller sends an alarm signal. When the fan rotational speed and the first pressure difference do not reach the alarm standard, the environment data monitoring method returns to step S01.

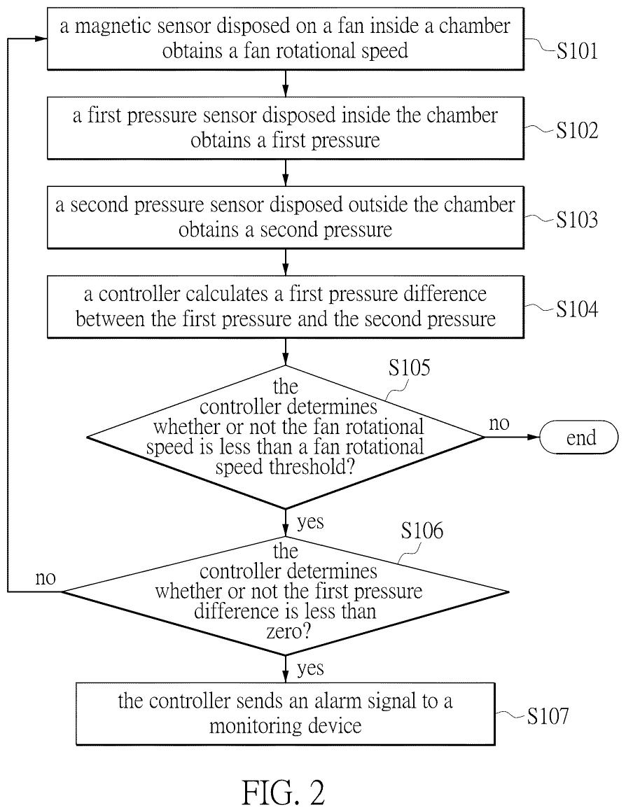

FIG. 2 is a flowchart of an environment data monitoring method according to a second embodiment of the present disclosure. Referring to FIG. 2, in step S101, a magnetic sensor disposed on a fan inside a chamber obtains a fan rotational speed. In step S102, a first pressure sensor disposed inside the chamber obtains a first pressure. In step S103, a second pressure sensor disposed outside the chamber obtains a second pressure. In step S104, a controller calculates a first pressure difference between the first pressure and the second pressure. In step S105, the controller determines whether or not the fan rotational speed is less than a fan rotational speed threshold (e.g., 7,000 rpm). When the fan rotational speed is less than the fan rotational speed threshold, step S105 is followed by step S106. When the fan rotational speed is not less than the fan rotational speed threshold, the environment data monitoring method ends. In other embodiments, the environment data monitoring method may return to step S101 for continuous environment monitoring. In step S106, the controller determines whether or not the first pressure difference is less than zero. When the first pressure difference is less than zero, step S106 is followed by step S107. When the first pressure difference is not less than zero, the environment data monitoring method returns to step S101. In step S107, environment data in the chamber has reached a first alarm standard preset by the controller, and so the controller sends an alarm signal to a monitoring device. To put it simply, the purpose of the preset first alarm standard is to warn the presence of a negative pressure between the inside and outside of the chamber due to damage of the fan. Under normal circumstances, a positive pressure should be maintained between the inside and outside of the chamber, and the positive pressure should not be too large or too small. For example, the positive pressure should be maintained at 0.3 hPa.

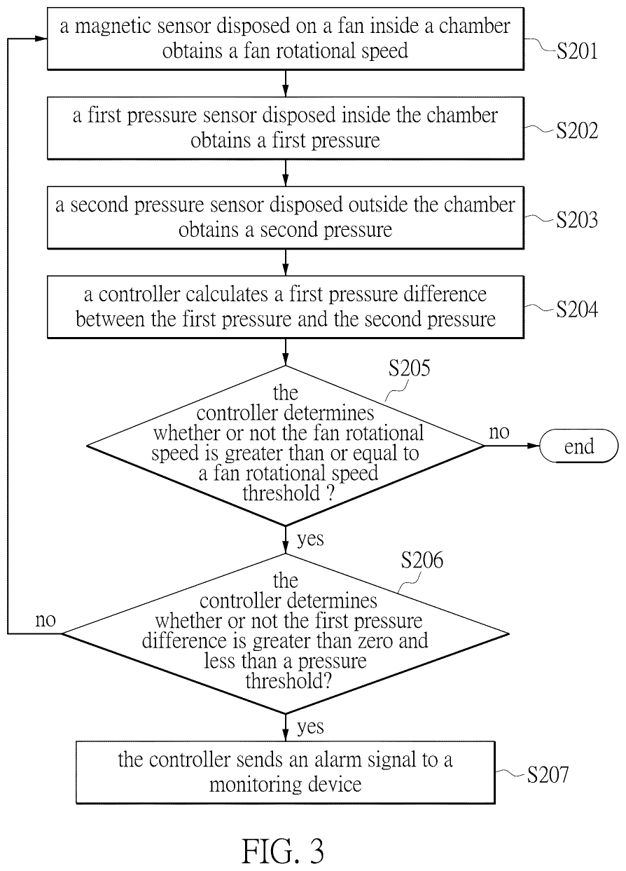

FIG. 3 is a flowchart of an environment data monitoring method according to a third embodiment of the present disclosure. Referring to FIG. 3, in step S201, a magnetic sensor disposed on a fan inside a chamber obtains a fan rotational speed. In step S202, a first pressure sensor disposed inside the chamber obtains a first pressure. In step S203, a second pressure sensor disposed outside the chamber obtains a second pressure. In step S204, a controller calculates a first pressure difference between the first pressure and the second pressure. In step S205, the controller determines whether or not the fan rotational speed is greater than or equal to a fan rotational speed threshold. When the fan rotational speed is greater than or equal to the fan rotational speed threshold, step S205 is followed by step S206. When the fan rotational speed is less than the fan rotational speed threshold, the environment data monitoring method ends. In other embodiments, the environment data monitoring method may return to step S201 for continuous environment monitoring. In step S206, the controller determines whether or not the first pressure difference is greater than zero and less than a pressure threshold (e.g., 0.3 hPa). When the first pressure difference is greater than zero and less than the pressure threshold, step S206 is followed by step S207. When the first pressure difference is less than zero, or greater than or equal to the pressure threshold, the environment data monitoring method returns to step S201. In step S207, environment data in the chamber has reached a second alarm standard preset by the controller, and so the controller sends an alarm signal to a monitoring device. To put it simply, the purpose of the preset second alarm standard is to warn that the pressure difference between the inside and outside of the chamber may be too small due to a pressure leak.

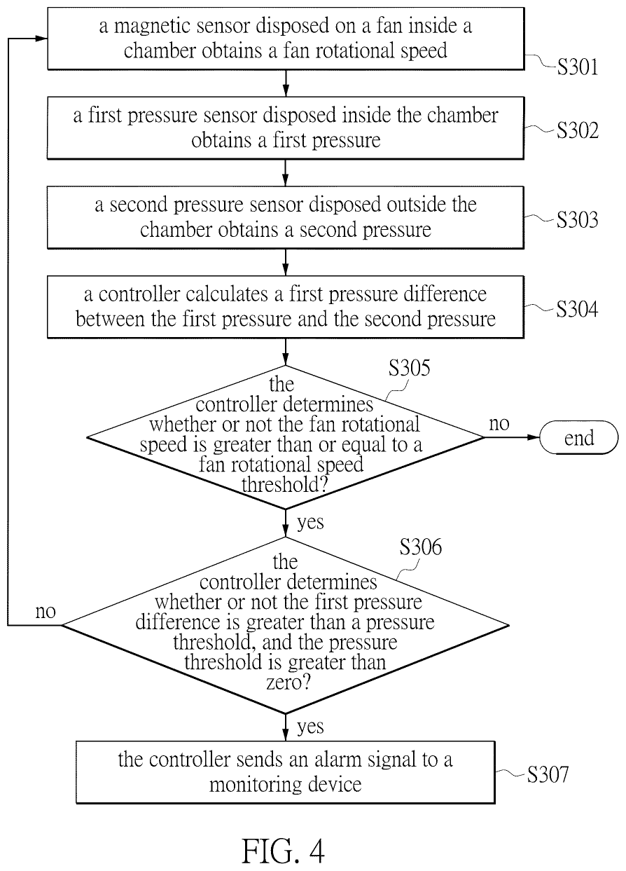

FIG. 4 is a flowchart of an environment data monitoring method according to a fourth embodiment of the present disclosure. Referring to FIG. 4, in step S301, a magnetic sensor disposed on a fan inside a chamber obtains a fan rotational speed. In step S302, a first pressure sensor disposed inside the chamber obtains a first pressure. In step S303, a second pressure sensor disposed outside the chamber obtains a second pressure. In step S304, a controller calculates a first pressure difference between the first pressure and the second pressure. In step S305, the controller determines whether or not the fan rotational speed is greater than or equal to a fan rotational speed threshold. When the fan rotational speed is greater than or equal to the fan rotational speed threshold, step S305 is followed by step S306. When the fan rotational speed is less than the fan rotational speed threshold, the environment data monitoring method ends. In other embodiments, the environment data monitoring method may return to step S301 for continuous environment monitoring. In step S306, the controller determines whether or not the first pressure difference is greater than a pressure threshold, and the pressure threshold is greater than zero. When the first pressure difference is greater than the pressure threshold, step S306 is followed by step S307. When the first pressure difference is less than or equal to the pressure threshold, the environment data monitoring method returns to step S301. In step S307, environment data in the chamber has reached a third alarm standard preset by the controller, and so the controller sends an alarm signal to a monitoring device. To put it simply, the purpose of the preset third alarm standard is to warn that the pressure difference between the inside and outside of the chamber may be too large due to a pressure feed.

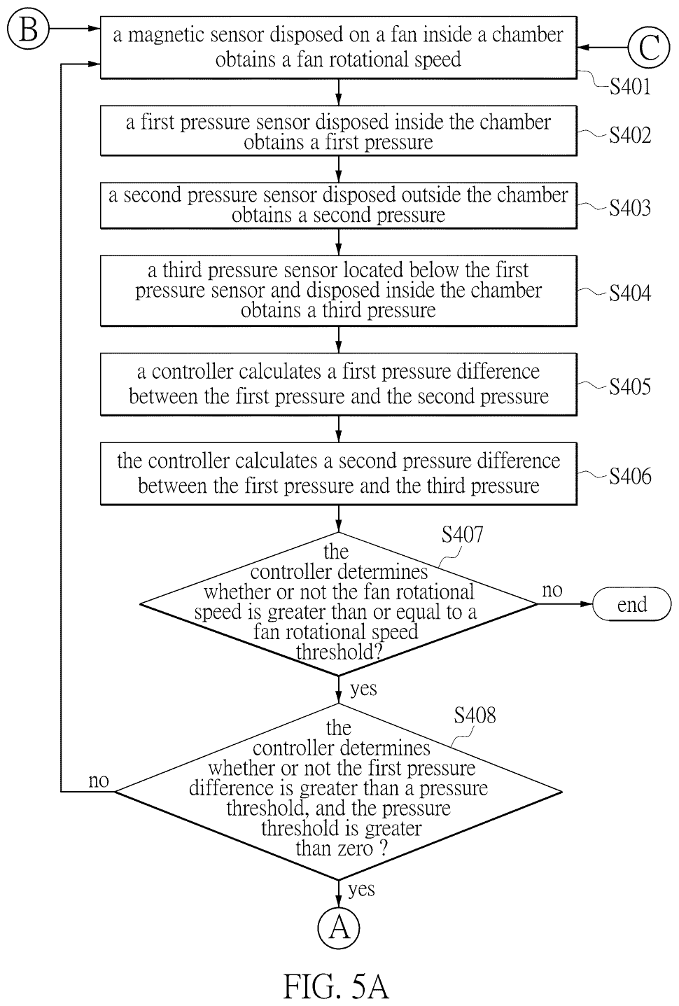

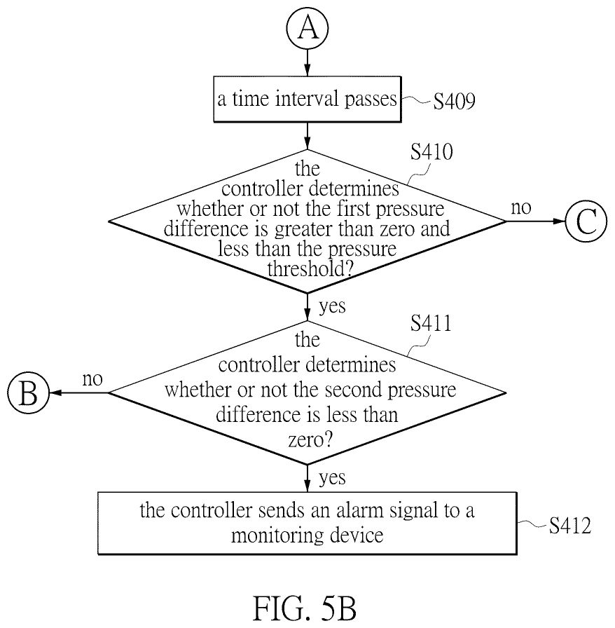

FIGS. 5A and 5B are flowcharts of an environment data monitoring method according to a fifth embodiment of the present disclosure. Referring to FIG. 5A, in step S401, a magnetic sensor disposed on a fan inside a chamber obtains a fan rotational speed. In step S402, a first pressure sensor disposed inside the chamber obtains a first pressure. In step S403, a second pressure sensor disposed outside the chamber obtains a second pressure. In step S404, a third pressure sensor located below the first pressure sensor and disposed inside the chamber obtains a third pressure. In step S405, a controller calculates a first pressure difference between the first pressure and the second pressure. In step S406, the controller calculates a second pressure difference between the first pressure and the third pressure. In step S407, the controller determines whether or not the fan rotational speed is greater than or equal to a fan rotational speed threshold. When the fan rotational speed is greater than or equal to the fan rotational speed threshold, step S407 is followed by step S408. When the fan rotational speed is less than the fan rotational speed threshold, the environment data monitoring method ends. In other embodiments, the environment data monitoring method may return to step S401 for continuous environment monitoring. In step S408, the controller determines whether or not the first pressure difference is greater than a pressure threshold, and the pressure threshold is greater than zero (e.g., 0.3 hPa). When the first pressure difference is greater than the pressure threshold, step S408 is followed by step S409. When the first pressure difference is not greater than the pressure threshold, the environment data monitoring method returns to step S401.

Referring to FIG. 5B, in step S409, a time interval passes. In step S410, the controller determines whether or not the first pressure difference is greater than zero and less than the pressure threshold. When the first pressure difference is greater than zero and less than the pressure threshold, step S410 is followed by step S411. When the first pressure difference is not greater than zero, or greater than or equal to the pressure threshold, the environment data monitoring method returns to step S401. In step S411, the controller determines whether or not the second pressure difference is less than zero. When the second pressure difference is less than zero, step S411 is followed by step S412. When the second pressure difference is not less than zero, the environment data monitoring method returns to step S401. In step S412, environment data in the chamber has reached a fourth alarm standard preset by the controller, and so the controller sends an alarm signal to a monitoring device. To put it simply, the purpose of the preset fourth alarm standard is to warn the presence of an airflow dead zone in the chamber.

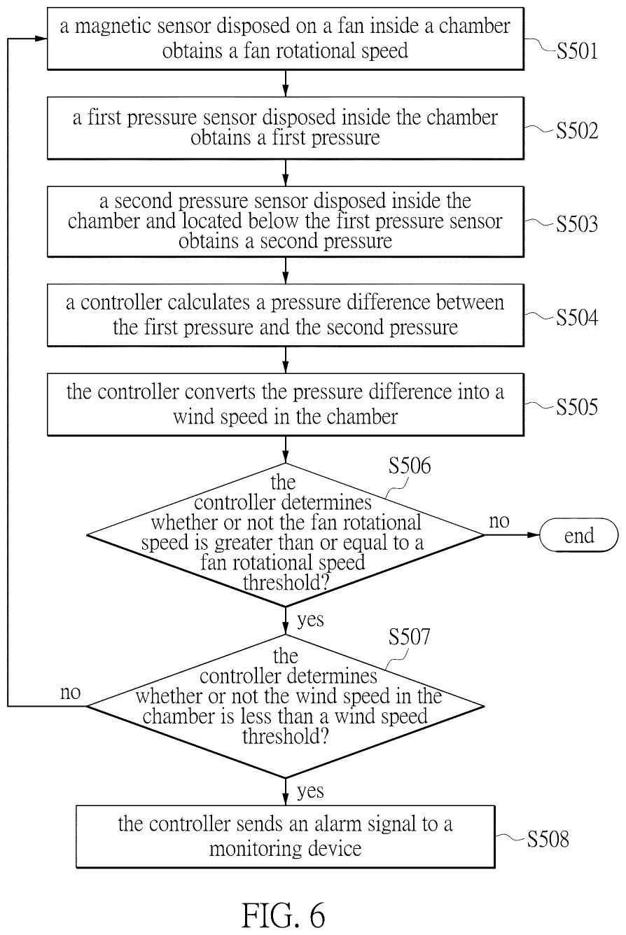

FIG. 6 is a flowchart of an environment data monitoring method according to a sixth embodiment of the present disclosure. Referring to FIG. 6, in step S501, a magnetic sensor disposed on a fan inside a chamber obtains a fan rotational speed. In step S502, a first pressure sensor disposed inside the chamber obtains a first pressure. In step S503, a second pressure sensor disposed inside the chamber and located below the first pressure sensor obtains a second pressure. In step S504, a controller calculates a pressure difference between the first pressure and the second pressure. In step S505, the controller converts the pressure difference into a wind speed in the chamber. The wind speed (m/s) in the chamber is 0.3*\sqrt{pressure difference (hpa)}.

In step S506, the controller determines whether or not the fan rotational speed is greater than or equal to a fan rotational speed threshold. When the fan rotational speed is greater than or equal to the fan rotational speed threshold, step S506 is followed by step S507. When the fan rotational speed is less than the fan rotational speed threshold, the environment data monitoring method ends. In other embodiments, the environment data monitoring method may return to step S501 for continuous environment monitoring. In step S507, the controller determines whether or not the wind speed in the chamber is less than a wind speed threshold (e.g., 0.4 m/s). When the wind speed in the chamber is less than the wind speed threshold, step S507 is followed by step S508. When the wind speed in the chamber is not less than the wind speed threshold, the environment data monitoring method returns to step S501. In step S508, environment data in the chamber at this moment has reached a fifth alarm standard preset by the controller, and so the controller sends an alarm signal to a monitoring device. To put it simply, the purpose of the preset fifth alarm standard is to warn that a fan filter is so severely blocked by impurities or dust that the wind speed in the chamber has become too small.

In other embodiments of the environment data monitoring method of the present disclosure, the five alarm standards shown in FIGS. 2 to 6 may be used in cooperation with each other, so as to provide warnings for various environmental conditions.

For example, when the fan rotational speed is less than the fan rotational speed threshold, the first alarm standard is implemented. When the fan rotational speed is greater than or equal to the fan rotational speed threshold, any one of the second alarm standard, the third alarm standard, the fourth alarm standard, and the fifth alarm standard, or any combination thereof is implemented.

For example, when the fan rotational speed is less the fan rotational speed threshold, the first alarm standard is implemented. When the fan rotational speed is greater than or equal to the fan rotational speed threshold, the second alarm standard and the fourth alarm standard are executed simultaneously or sequentially.

For example, when the fan rotational speed is less the fan rotational speed threshold, the first alarm standard is implemented. When the fan rotational speed is greater than or equal to the fan rotational speed threshold, the third alarm standard and the fifth alarm standard are executed simultaneously or sequentially.

For example, when the fan rotational speed is greater than or equal to the fan rotational speed threshold, the second alarm standard, the third alarm standard, and the fourth alarm standard are executed simultaneously or sequentially.

For example, when the fan rotational speed is greater than or equal to the fan rotational speed threshold, the third alarm standard and the fourth alarm standard are executed simultaneously or sequentially.

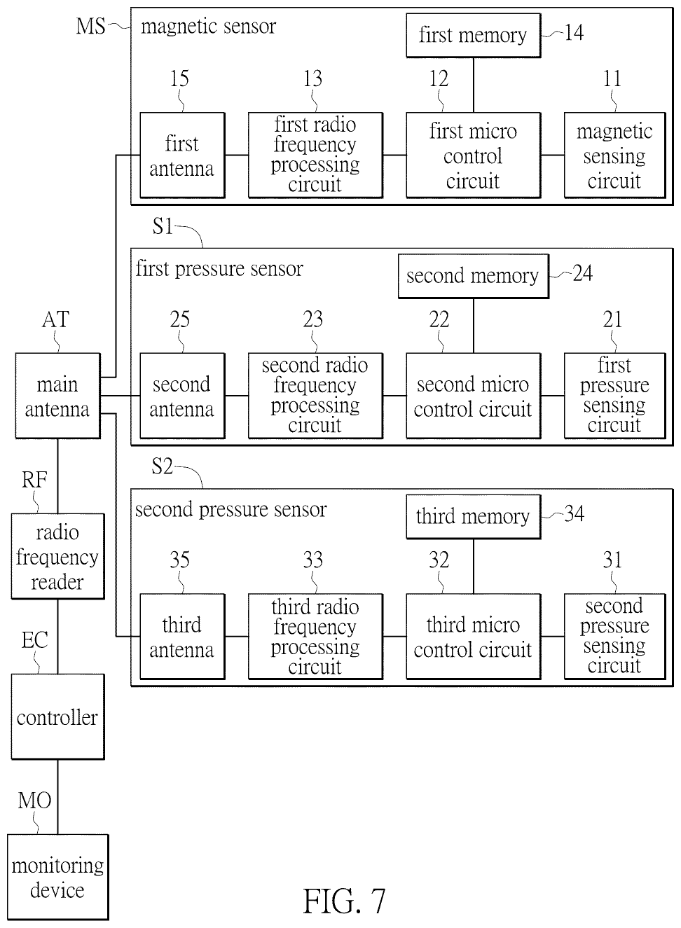

FIG. 7 is a functional block diagram of an environment data monitoring system according to the first embodiment of the present disclosure. Referring to FIG. 7, the environment data monitoring system includes a magnetic sensor MS, a first pressure sensor S1 located inside a chamber, a second pressure sensor S2 located outside the chamber, a main antenna AT, a radio frequency reader RF, and a controller EC. The magnetic sensor MS is disposed on a motor of a fan located in the chamber, and is a magnetic sensing radio frequency tag. The magnetic sensor MS includes a magnetic sensing circuit 11, a first micro control circuit 12, a first radio frequency processing circuit 13, a first memory 14, and a first antenna 15. The first micro control circuit 12 is electrically connected to the magnetic sensing circuit 11, the first radio frequency processing circuit 13, and the first memory 14, and the first radio frequency processing circuit 13 is electrically connected to the first micro control circuit 12 and the first antenna 15.

The first pressure sensor S1 is a pressure sensing radio frequency tag, and is located at a first position in the chamber. The first pressure sensor S1 includes a first pressure sensing circuit 21, a second micro control circuit 22, a second radio frequency processing circuit 23, a second memory 24, and a second antenna 25. The micro control circuit 22 is electrically connected to the first pressure sensing circuit 21 and the second memory 24, and the second radio frequency processing circuit 23 is electrically connected to the second micro control circuit 22 and the second antenna 25.

The second pressure sensor S2 is a pressure sensing radio frequency tag, and the second pressure sensor S2 includes a second pressure sensing circuit 31, a third micro control circuit 32, a third radio frequency processing circuit 33, a third memory 34, and a third antenna 35. The third micro control circuit 32 is electrically connected to the second pressure sensing circuit 31 and the third memory 34, and the third radio frequency processing circuit 33 is electrically connected to the third micro control circuit 32 and the third antenna 35.

The main antenna AT is located inside the chamber, and the radio frequency reader RF and the controller EC are located outside the chamber. The radio frequency reader RF is electrically connected to the main antenna AT by a radio frequency cable, the radio frequency reader RF is electrically connected to the controller EC, and the controller EC is electrically connected to a monitoring device MO.

The main antenna AT continuously sends radio frequency signals, and the first antenna 15 of the magnetic sensor MS receives the radio frequency signals from the main antenna AT to obtain energy. When the magnetic sensor MS obtains sufficient energy for activation, the magnetic sensing circuit 1 of the magnetic sensor MS detects a fan rotational speed of the fan and outputs the fan rotational speed to the first micro control circuit 12 of the magnetic sensor MS. Then, the first micro control circuit 12 outputs the fan rotational speed to the first radio frequency processing circuit 13 and the first memory 14 of the magnetic sensor MS. The first radio frequency processing circuit 13 sends a first radio frequency signal by the first antenna 15, and the fan rotational speed is embedded in the first radio frequency signal. Finally, the radio frequency reader RF receives the first radio frequency signal by the main antenna AT to read the fan rotational speed of the fan.

Based on the above, the magnetic sensor MS does not need a built-in power supply or an external power supply, and may be activated by receiving the energy of the radio frequency signal provided by the main antenna AT. The first pressure sensor S1 also has an activation function which is the same as that of the magnetic sensor MS. The first pressure sensor S1 is activated by receiving the energy provided by the main antenna AT, and the activated first pressure sensor S1 detects a first pressure at the first position in the chamber and transmits a second radio frequency signal toward the main antenna AT. The first pressure (a pressure in the chamber) is embedded in the second radio frequency signal. The radio frequency reader RF receives the second radio frequency signal by the main antenna AT to read the first pressure.

The second pressure sensor S2 also has an activation function which is the same as that of the first pressure sensor S1. The second pressure sensor S2 is activated by receiving the energy provided by the main antenna AT. The activated second pressure sensor S2 detects a second pressure outside the chamber and transmits a third radio frequency signal toward the main antenna AT. The second pressure (a pressure outside the chamber) is embedded in the third radio frequency signal. The radio frequency reader RF receives the third radio frequency signal by the main antenna AT to read the second pressure.

When the radio frequency reader RF reads the fan rotational speed, the first pressure, and the second pressure, the radio frequency reader RF transmits the fan rotational speed, the first pressure, and the second pressure to the controller EC. When the controller EC reads the fan rotational speed, the first pressure, and the second pressure, the controller EC calculates a pressure difference between the first pressure and the second pressure. Then, the controller EC determines whether or not the fan rotational speed and the pressure difference reach an alarm standard. When the fan rotational speed and the pressure difference reach the alarm standard, the controller EC sends an alarm signal to the monitoring device MO.

The alarm standard may be preset in the controller EC according to different practical requirements. For example, when the fan rotational speed is less than a fan rotational speed threshold and the pressure difference is less than zero, a first alarm standard preset by the controller EC is reached. At this time, the controller EC sends an alarm signal to warn the presence of a negative pressure between the inside and outside of the chamber due to damage of the fan.

When the fan rotational speed is greater than or equal to the fan rotational speed threshold and the pressure difference is greater than zero and less than a pressure threshold, a second alarm standard preset by the controller EC is reached. At this time, the controller EC sends an alarm signal to warn that the pressure difference between the inside and outside of the chamber may be too small due to a pressure leak.

When the fan rotational speed is greater than or equal to the fan rotational speed threshold and the pressure difference is greater than the pressure threshold, a third alarm standard preset by the controller EC is reached. At this time, the controller EC sends an alarm signal to warn that the pressure difference between the inside and outside of the chamber may be too large due to a pressure feed.

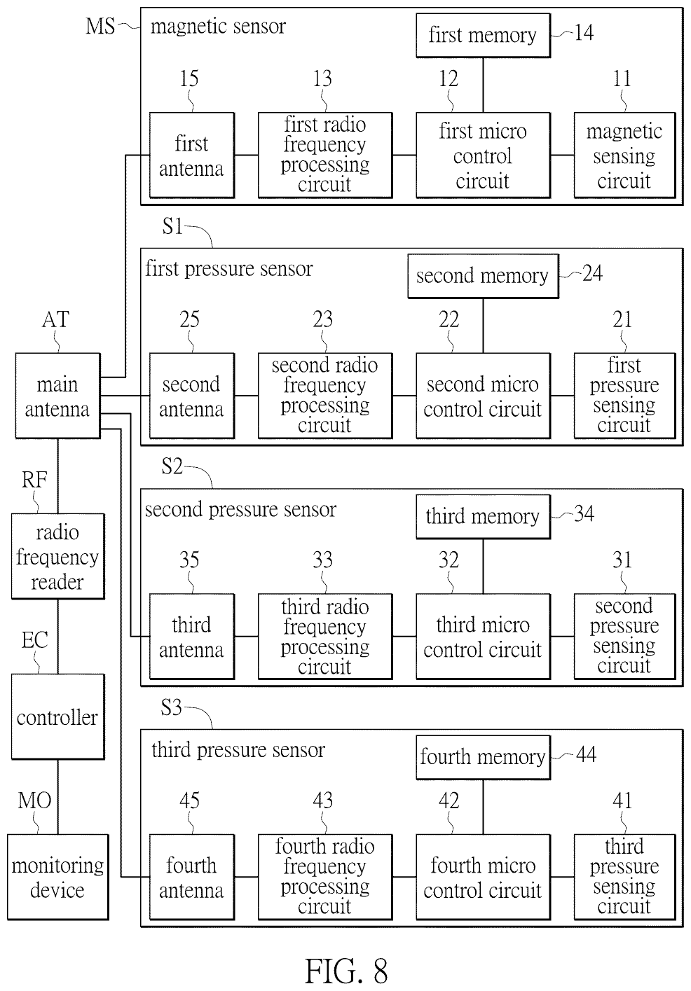

FIG. 8 is a functional block diagram of an environment data monitoring system according to the fifth embodiment of the present disclosure. Comparing FIG. 8 with FIG. 7, the environment data monitoring system in FIG. 8 further includes a third pressure sensor S3. The third pressure sensor S3 is located at a second position in the chamber, and the second position is located below the first position. The third pressure sensor S3 is a pressure sensing radio frequency tag, and the third pressure sensor S3 includes a third pressure sensing circuit 71, a fourth micro control circuit 72, a fourth radio frequency processing circuit 73, a fourth memory 74, and a fourth antenna 75. The fourth micro control circuit 72 is electrically connected to the third pressure sensing circuit 71 and the fourth memory 74, and the fourth radio frequency processing circuit 74 is electrically connected to the fourth micro control circuit 72 and the fourth antenna 75.

The main antenna AT continuously sends radio frequency signals. The fourth antenna 75 of the third pressure sensor S3 receives the radio frequency signals from the main antenna AT to obtain energy. When the third pressure sensor S3 obtains sufficient energy for activation, the third pressure sensing circuit 71 of the third pressure sensor S3 detects a third pressure at the second position in the chamber and outputs the third pressure to the fourth micro control circuit 72. Then, the fourth micro control circuit 72 outputs the third pressure to the fourth radio frequency processing circuit 73 and the fourth memory 74 of the third pressure sensor S3. The fourth radio frequency processing circuit 73 sends a fourth radio frequency signal by the fourth antenna 75. The third pressure (a pressure in the chamber) is embedded in the fourth radio frequency signal. The radio frequency reader RF receives the fourth radio frequency signal by the main antenna AT to read the third pressure.

When the radio frequency reader RF reads the fan rotational speed, the first pressure, the second pressure, and the third pressure, the radio frequency reader RF transmits the fan rotational speed, the first pressure, the second pressure, and the third pressure to the controller EC. When the controller EC reads the fan rotational speed, the first pressure, the second pressure, and the third pressure, the controller EC calculates a first pressure difference between the first pressure and the second pressure and a second pressure difference between the first pressure and the third pressure. Firstly, the controller EC determines whether or not the fan rotational speed is greater than or equal to a fan rotational speed threshold. When the fan rotational speed is greater than or equal to the fan rotational speed threshold, the controller EC determines whether or not the first pressure difference is greater than a pressure threshold at a first time point. The pressure threshold is greater than zero. When the first pressure difference is greater than the pressure threshold, the controller EC determines whether or not the first pressure difference is greater than zero and less than the pressure threshold at a second time point. A time interval between the second time point and the first time point is preset by the controller EC. When the first pressure difference is greater than zero and less than the pressure threshold, the controller EC determines whether or not the second pressure difference is less than zero. When the second pressure difference is less than zero, a fourth alarm standard preset by the controller EC is reached. At this time, there may be an airflow dead zone present in the chamber, so that the controller EC sends an alarm signal.

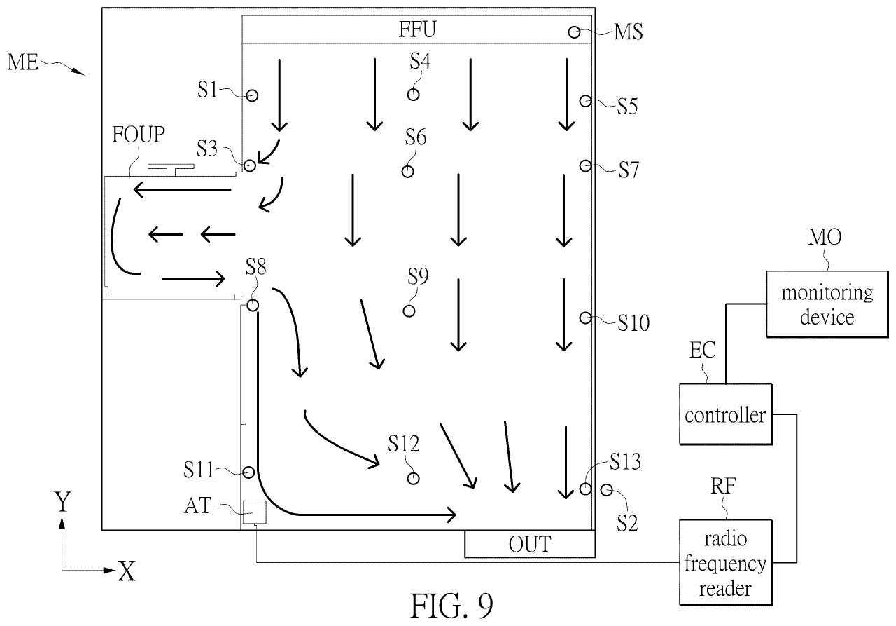

FIG. 9 is a schematic diagram of an environment data monitoring apparatus according to the first embodiment of the present disclosure. Referring to FIG. 8 and FIG. 9, the environment data monitoring apparatus includes a machine device having a chamber and a fan FFU and an environment data monitoring system, the machine device is a micro-clean room (mini environment) ME, and a wafer transfer box FOUP is connected to one side of the micro-clean room ME. The environment data monitoring system includes a magnetic sensor MS, first to thirteenth pressure sensors S1-S13, a main antenna AT, a radio frequency reader RF, and a controller EC. The magnetic sensor MS is disposed on the fan FFU. When the fan FFU is activated, airflow occurs in the micro-clean room ME (as indicated by directions of arrows). Due to the airflow, particles suspended in the air are discharged from an exhaust port OUT of the micro-clean room ME.

The first pressure sensor S1, a fourth pressure sensor S4, and a fifth pressure sensor S5 are located in the micro-clean room ME, and their Cartesian coordinates are respectively (x1, y1), (x2, y1), and (x3, y1). The third pressure sensor S3, a sixth pressure sensor S6, and a seventh pressure sensor S7 are located in the micro-clean room ME, their Cartesian coordinates are respectively (x1, y2), (x2, y2), and (x3, y2), and y2 is less than y1. An eighth pressure sensor S8, a ninth pressure sensor S9, and a tenth pressure sensor S10 are located in the micro-clean room ME, their Cartesian coordinates are respectively (x1, y3), (x2, y3), and (x3, y3), and y3 is less than y2. An eleventh pressure sensor S11, a twelfth pressure sensor SS12, and a thirteenth pressure sensor S13 are located in the micro-clean room ME, their Cartesian coordinates are respectively (x1, y4), (x2, y4) and (x3, y4), and y4 is less than y3. The second pressure sensor S2 is located outside the micro-clean room ME, and its Cartesian coordinate is (x4, y4).

The main antenna AT is, for example, an ultra-high frequency (UHF) antenna. The main antenna AT is located inside the micro-clean room ME. The radio frequency reader RF is located outside the micro-clean room ME, and is electrically connected to the main antenna AT by a radio frequency cable. The radio frequency reader RF is electrically connected to the controller EC in a wired or a wireless manner (such as Ethernet), and the controller EC is electrically connected to the monitoring device MO in a wired or a wireless manner.

When the magnetic sensor MS receives sufficient energy from the main antenna AT for activation, the magnetic sensor MS detects the fan rotational speed of the fan FFU. Then, the magnetic sensor MS sends a radio frequency signal embedded with the fan rotational speed. The radio frequency reader RF reads the fan rotational speed from the magnetic sensor MS, and then transmits the fan rotational speed to the controller EC.

When the first pressure sensor S1 to the thirteenth pressure sensor S13 receive from the main antenna AT sufficient energy for activation, the first pressure sensor S1 to the thirteenth pressure sensor S13 respectively detect a plurality of different pressures corresponding to different Cartesian coordinates. Then, the first to thirteenth pressure sensors S1 to S13 respectively send a plurality of radio frequency signals, and the radio frequency signals are respectively embedded with the plurality of different pressures. The radio frequency reader RF reads the plurality of different pressures from the first pressure sensor S1 to the thirteenth pressure sensor S13, and transmits the plurality of different pressures to the controller EC.

Finally, the controller EC reads the fan rotational speed and the plurality of pressures, and determines whether or not environment data in the micro-clean room ME reaches an alarm standard. When the environment data of any one of the first pressure sensor S1 to the thirteenth pressure sensor S13 in the micro-clean room ME reaches the alarm standard, the controller EC sends an alarm signal to the monitoring device MO.

### Beneficial Effects of the Embodiments

In conclusion, in the environment data monitoring method, the environment data monitoring system, and the environment data monitoring apparatus provided by the present disclosure, as long as the fan rotational speed, the pressure difference between the pressure inside the chamber and the pressure outside of the chamber, or the pressure inside the chamber is detected to be abnormal, the alarm signal is immediately sent to the monitoring device, so as to eliminate abnormal situations as soon as possible.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An environment data monitoring method, comprising:
obtaining, by a magnetic sensor, a fan rotational speed;
obtaining, by a first pressure sensor, a first pressure;
obtaining, by a second pressure sensor, a second pressure;
calculating, by a controller, a first pressure difference between the first pressure and the second pressure;
determining, by the controller, whether or not the fan rotational speed and the first pressure difference reach an alarm standard; and
sending, by the controller, an alarm signal when the fan rotational speed and the first pressure difference reach the alarm standard.

2. The environment data monitoring method according to claim 1, wherein the alarm standard includes the fan rotational speed being less than a fan rotational speed threshold and the first pressure difference being less than zero.

3. The environment data monitoring method according to claim 1, wherein the alarm standard includes the fan rotational speed being greater than or equal to a fan rotational speed threshold and the first pressure difference being greater than zero and less than a pressure threshold.

4. The environment data monitoring method according to claim 1, wherein the alarm standard includes the fan rotational speed being greater than or equal to a fan rotational speed threshold and the first pressure difference being greater than a pressure threshold, and the pressure threshold is greater than zero.

5. The environment data monitoring method according to claim 1, further comprising: obtaining a third pressure by a third pressure sensor located below the first pressure sensor; and calculating, by the controller, a second pressure difference between the first pressure and the third pressure; wherein the alarm standard includes the fan rotational speed being greater than or equal to a fan rotational speed threshold and the first pressure difference being greater than zero and less than a pressure threshold, and the second pressure difference is less than zero.

6. The environment data monitoring method according to claim 5, wherein the alarm standard further includes the first pressure difference being greater than the pressure threshold before the first pressure difference is greater than zero and less than the pressure threshold and after the fan rotational speed is greater than or equal to the fan rotational speed threshold.

7. The environment data monitoring method according to claim 1, further comprising: converting, by the controller, the first pressure difference into a wind speed; wherein the alarm standard includes the fan rotational speed being greater than or equal to a fan rotational speed threshold and the wind speed being less than a wind speed threshold, and the wind speed threshold is greater than zero.

8. An environment data monitoring system, comprising:
a magnetic sensor for obtaining a fan rotational speed;
a first pressure sensor for obtaining a first pressure;
a second pressure sensor for obtaining a second pressure;
a main antenna communicatively connected with the magnetic sensor, the first pressure sensor, and the second pressure sensor;
a radio frequency reader electrically connected to the main antenna; and
a controller electrically connected to the radio frequency reader;
wherein the controller calculates a first pressure difference between the first pressure and the second pressure, and determines whether or not the fan rotational speed and the first pressure difference reach an alarm standard;
wherein, when the fan rotational speed and the first pressure difference reach the alarm standard, the controller sends an alarm signal.

9. The environment data monitoring system according to claim 8, wherein the magnetic sensor is a magnetic sensing radio frequency tag, the first pressure sensor is a pressure sensing radio frequency tag, and the second pressure sensor is an another pressure sensing radio frequency tag.

10. The environment data monitoring system according to claim 8, further comprising a third pressure sensor, wherein the third pressure sensor is located below the first pressure sensor, the third pressure sensor obtains a third pressure, and the controller calculates a second pressure difference between the first pressure and the third pressure; wherein the alarm standard includes the fan rotational speed being greater than or equal to a fan rotational speed threshold and the first pressure difference being greater than zero and less than a pressure threshold, and the second pressure difference is less than zero.

11. An environment data monitoring apparatus, comprising:
a machine device having a chamber and a fan; and
an environment data monitoring system;
wherein the environment data monitoring system includes:
a magnetic sensor for obtaining a fan rotational speed;
a first pressure sensor for obtaining a first pressure;
a second pressure sensor for obtaining a second pressure;
a main antenna communicatively connected with the magnetic sensor, the first pressure sensor, and the second pressure sensor;
a radio frequency reader electrically connected to the main antenna; and
a controller electrically connected to the radio frequency reader;
wherein the controller calculates a first pressure difference between the first pressure and the second pressure, and determines whether or not the fan rotational speed and the first pressure difference reach an alarm standard;
wherein, when the fan rotational speed and the first pressure difference reach the alarm standard, the controller sends an alarm signal.

12. The environment data monitoring apparatus according to claim 11, wherein the machine device is a micro-clean room and the magnetic sensor is disposed on the fan.

13. The environment data monitoring apparatus according to claim 11, wherein the magnetic sensor is a magnetic sensing radio frequency tag, the first pressure sensor is a pressure sensing radio frequency tag, and the second pressure sensor is an another pressure sensing radio frequency tag.

14. The environment data monitoring apparatus according to claim 11, wherein the second pressure sensor is located outside the chamber and the alarm standard includes the fan rotational speed being less than a fan rotational speed threshold and the first pressure difference being less than zero.

15. The environment data monitoring apparatus according to claim 11, wherein the second pressure sensor is located outside the chamber and the alarm standard includes the fan rotational speed being greater than or equal to a fan rotational speed threshold and the first pressure difference being greater than zero and less than a pressure threshold.

16. The environment data monitoring apparatus according to claim 11, wherein the second pressure sensor is located outside the chamber; wherein the alarm standard includes the fan rotational speed being greater than or equal to a fan rotational speed threshold and the first pressure difference being greater than a pressure threshold, and the pressure threshold is greater than zero.

17. The environment data monitoring apparatus according to claim 11, wherein the second pressure sensor is located outside the chamber, the environment data monitoring apparatus further comprises a third pressure sensor located inside the chamber and below the first pressure sensor, the third pressure sensor obtains a third pressure, and the controller calculates a second pressure difference between the first pressure and the third pressure; wherein the alarm standard includes the fan rotational speed being greater than or equal to a fan rotational speed threshold and the first pressure difference being greater than zero and less than a pressure threshold, and the second pressure difference is less than zero.

18. The environment data monitoring apparatus according to claim 17, wherein the alarm standard further includes the first pressure difference being greater than the pressure threshold before the first pressure difference is greater than zero and less than the pressure threshold and after the fan rotational speed is greater than or equal to the fan rotational speed threshold.

19. The environment data monitoring apparatus according to claim 11, wherein the second pressure sensor is located inside the chamber, and the controller converts the first pressure difference into a wind speed; wherein the alarm standard includes the fan rotational speed being greater than or equal to a fan rotational speed threshold and the wind speed being less than a wind speed threshold, and the wind speed threshold is greater than zero.
